(19) United States
(12) Patent Application Publication
(10) Pub. No.: US 2004/0017921 A1
(43) Pub. Date: Jan. 29, 2004

(54) Electrical impedance based audio compensation in audio devices and methods therefor

(76) Inventor: Jose Ricardo Baddini Mantovani, Mundelein, IL (US)

Correspondence Address: MOTOROLA INC, 600 NORTH US HIGHWAY 45, LIBERTYVILLE, IL, 60048-5343, US

(21) Appl. No.: 10/206,704

(22) Filed: Jul. 26, 2002

(51) Int. Cl. H03G 11/00; H04R 29/00; H04B 15/00

(52) U.S. Cl. 381/94.9; 381/59; 381/55

(57) ABSTRACT

An audio device, for example a wireless communications handset, including a sound transducer (410) coupled to a compensated audio signal output of an audio compensator (450), a mismatch detection circuit (430) having a first input coupled to the compensated audio signal output of the audio compensator (450), the mismatch detection circuit (430) having a second input coupled to the sound transducer (410), the mismatch detecting circuit having an output corresponding to a mismatch between a reference electrical impedance of the sound transducer and an actual electrical impedance of the sound transducer, a compensation estimator (440) having an input coupled to the output of the mismatch detection circuit, the compensation estimator having an audio compensation output coupled to a compensation input of the audio compensator.

### FIELD OF THE INVENTIONS

The present inventions relate generally to audio compensation in electrical devices, and more particularly to electrical impedance based audio compensation in electrical devices, for example wireless communications devices, subject to variable acoustic impedance, audio compensation systems and circuits, and methods therefor.

### BACKGROUND OF THE INVENTIONS

In wireless communications handsets and other devices housing an audio speaker for use in proximity to a human ear, it is well known changes in the coupling, or sometimes referred to as leakage, between the housing and the user's ear changes the acoustic impedance of the speaker. Acoustic impedance is generally a ratio of sound pressure on a surface to sound flux through the surface, expressed in acoustic ohms. Changes in acoustic impedance may result in dramatic, often adverse, changes in audio quality, including changes in audio frequency response and variations in loudness.

The substantial variability in the human ear size and shape also affects the coupling in ear-mounted audio devices, since it is difficult to provide a one-size-fits-all ear mount. The variation in acoustic quality is apparent in wireless communications handsets and other audio devices, particularly those having small form-factors, which provide limited areas on which the user's ear may be placed for listening.

Presently, acoustic engineers select a combination of speaker, housing enclosure and preconditioning electrical circuitry to optimize audio quality, which is judged generally on the flatness and variability of the frequency response over a range of audio frequencies, typically 300 Hz to 4 kHz.

U.S. Pat. No. 6,321,070 entitled “Portable Electronic Device With A Speaker Assembly” discloses, for example, mechanical housing configurations for producing an audio frequency response that is relatively independent of the coupling, or audio leakage, between the user's ear and the handset housing.

The various aspects, features and advantages of the present invention will become more fully apparent to those having ordinary skill in the art upon careful consideration of the following Detailed Description of the Invention and the accompanying drawings described below.

### BRIEF DESCRIPTION OF THE DRAWINGS

FIG. 1 is an exemplary electronics audio device.

FIG. 2 is a partial view of an exemplary sound transducer in a housing having an ear-mount.

FIG. 3 is an exemplary audio compensation process flow diagram.

FIG. 4 is an exemplary schematic circuit for detecting and compensating for changes in electrical impedance of a sound transducer.

FIG. 5 is an exemplary electrical mismatch detecting circuit diagram.

FIG. 6 is a graphical illustration of speaker impedance magnitude versus frequency for a speaker with a sealed coupling and for the same speaker with an unsealed coupling.

FIG. 7 is an exemplary audio compensation process flow diagram.

### DETAILED DESCRIPTION OF THE INVENTIONS

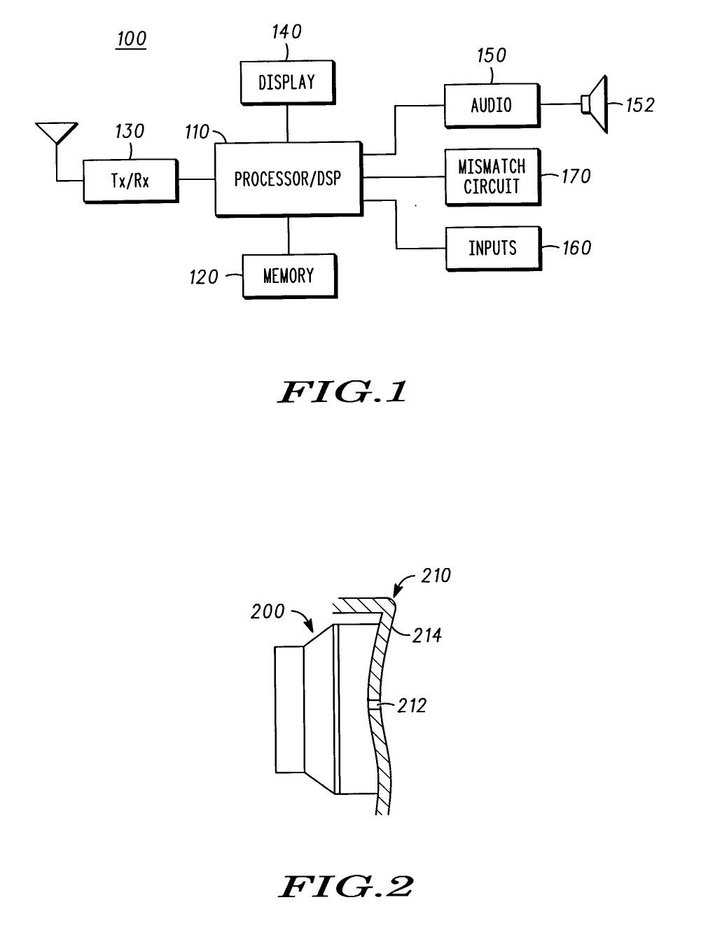

FIG. 1 is an exemplary electronics device having a sound transducer in the form of a wireless communications device 100, although in other embodiments the electronics device may be some other audio device, for example an audio sound system or a portion thereof, or an audio headset or headset accessory, etc.

The exemplary wireless communications device 100 comprises generally a processor/DSP 110 coupled to memory 120, for example a ROM and RAM. The processor/ DSP may be an integrated circuit or discrete circuits. The exemplary device also includes wireless transceiver 130 and a display 140, both coupled to the processor/DSP 110. An audio driver 150 and a sound transducer 152, for example a dynamic or piezoelectric speaker, is also coupled to the processor/DSP 110. The exemplary device includes inputs 160, for example, a keypad and/or scroll device or a pointer device, a microphone, etc. The exemplary wireless device also includes generally other inputs and outputs typical wireless communications devices.

Generally, the sound transducer is any sound transducer device that is subject to a changing acoustical impedance characteristic dependent on the manner of its use or some other variable factor, for example proximity of the user's ear relative to the sound transducer, or the amount of leakage between the users ear and a housing in which the sound transducer is disposed, referred to generally as a coupling.

FIG. 2 illustrates an exemplary sound transducer 200 disposed in a housing 210 having one or more ports 212 through which sound emanates from the sound transducer. The housing 210 may have an ear-mount 214, near or against which a user's ear is placed for listening to the sound transducer. The housing 210 may be that of a wireless communications handset, or a telephone receiver handset, or an audio headset.

According to the invention generally, in FIG. 3, at block 310, an electrical impedance of the sound transducer changes in response to changes in an acoustic impedance of the sound transducer. The acoustic impedance may change, for example, based on the proximity of an object or the user to the sound transducer. At block 320, an electrical parameter that changes with the changing electrical impedance of the sound transducer is detected, for example with an electrical mismatch detection circuit, to measure or gauge the changing acoustical impedance.

The measured changes in the electrical parameter associated with changes in the acoustic impedance of the speaker are used generally as the basis for a control signal. In one embodiment in FIG. 3, at block 330, changes in acoustic impedance are compensated by changing an electrical characteristic of an audio signal sent to the sound transducer based on the changing electrical parameter, for example the frequency response and/or gain of an audio signal sent to the speaker may be compensated based upon the detected electrical parameter.

In one embodiment, the electrical parameter that changes with the changing electrical impedance (and the changing acoustic impedance) of the sound transducer is measured or detected by generating an electrical signal indicative of a mismatch between a reference electrical impedance of the sound transducer and an actual electrical impedance of the sound transducer.

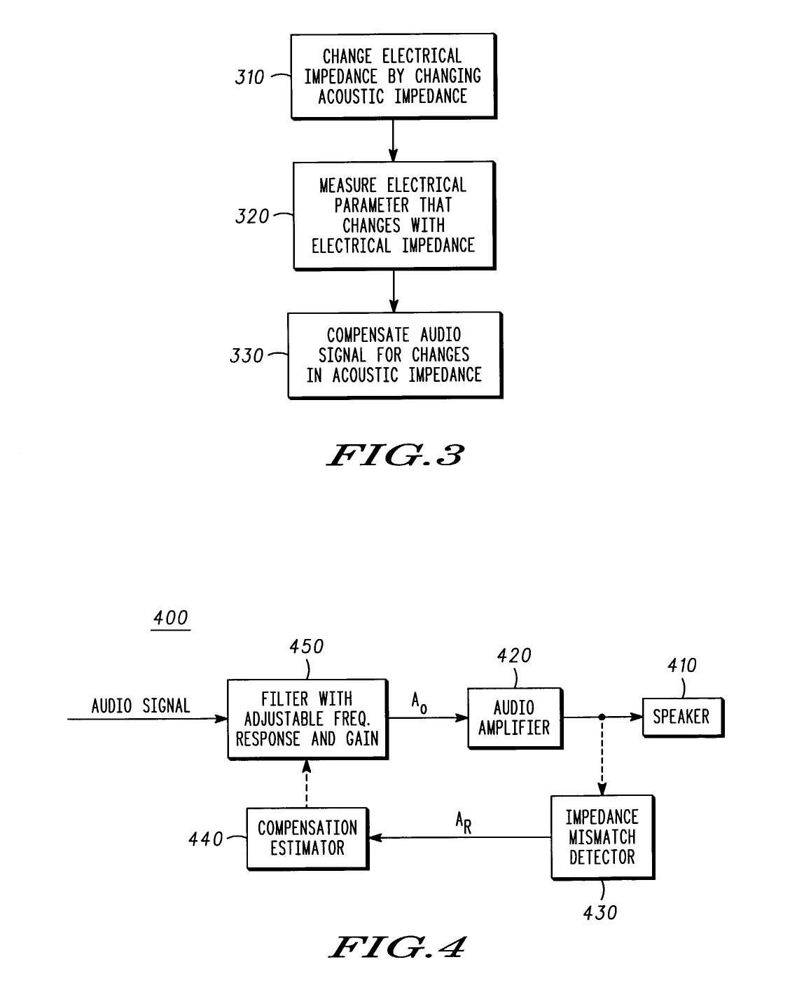

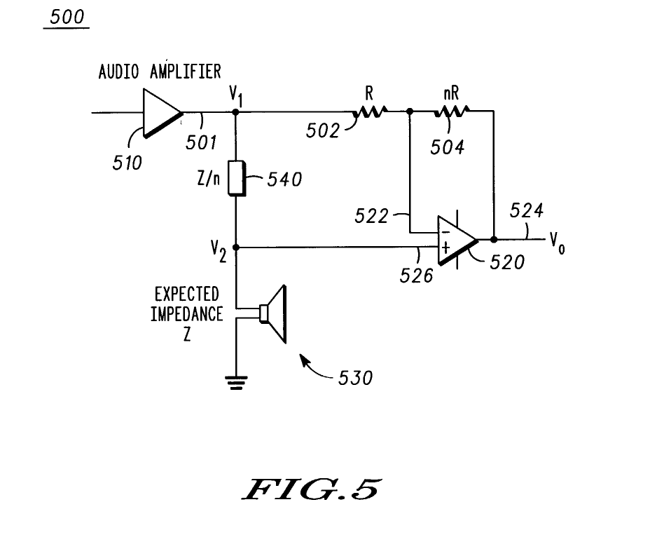

FIG. 4 is a schematic diagram of an exemplary circuit 400 for detecting and compensating for changes in electrical impedance. The exemplary circuit includes a sound transducer 410 having an audio signal input, which it typically coupled to an audio signal source, for example the output of an audio amplifier 420. A mismatch detecting circuit 430 having an input coupled to the input of the sound transducer includes an output that changes with changes in the electrical impedance of the sound transducer.

In the exemplary embodiment of FIG. 1, the exemplary electronics device 100 includes a mismatch detection circuit 170 having an output that corresponds to changes in the electrical impedance of the sound transducer. And the audio signal originates from the processor/DSP 110, and the audio driver 150 amplifies the signal to the speaker 152.

In FIG. 4, the output of the mismatch detection circuit 430 is used generally as a control signal, for example to compensate the audio signal sent to the sound transducer based upon changes in the electrical impedance thereof. Alternatively, the output of the mismatch detection circuit may be used to control some other operation, for example it may control a telephone hands-free loudspeaker mode based upon detecting changes in electrical impedance corresponding to changes in acoustic impedance dependent on the proximity of a user speaking into a microphone. In this exemplary application, the mismatch detection circuit operates effectively as a proximity detector.

FIG. 5 is a more particular embodiment of an exemplary mismatch detection circuit 500 comprising generally a signal input 501 coupled to a signal source, for example an output of audio amplifier circuit 510. The mismatch detection circuit includes an operational amplifier 520 having its inverting input 522 coupled to the signal input 501 by an input resistor 502. The inverting input 522 of the operational amplifier is also coupled to an output 524 thereof by a feedback resistor 504. A noninverting input 526 of the operational amplifier is coupled to a sound transducer 530. The sound transducer 530 and the noninverting input 526 of the operational amplifier 520 are both coupled to the signal input 501 by an impedance device 540. In other embodiments, the mismatch detection circuit output may have some other value for the case where the speaker impedance is at the reference impedance.

The exemplary mismatch detection circuit 500 detects changes in the electrical impedance of the sound transducer 530, for example changes in electrical impedance resulting from changes in acoustic impedance caused by an changes in coupling between the sound transducer and the user's ear or changes in the proximity of some other object. In one embodiment, the values of input resistor 502, the feedback resistor 504 and the impedance device 540 are chosen so that the operational amplifier 520 has a zero output for a reference impedance of the audio sound device 530 when the impedance of the speaker 530 is at a reference impedance, for example when the electrical impedance of the sound transducer is at its expected impedance.

The expected impedance is the inherent electrical impedance of the sound transducer in a well-known acoustic environment, like when it's perfectly coupled against a user's ear. The electrical impedance of the sound transducer changes when the acoustic environment changes, for example when an object, like the users ear, moves toward or away from the sound transducer. In embodiments where the sound transducer is a dynamic speaker, its impedance is largely resistive. In embodiments where the sound transducer is a piezoelectric device, its impedance is largely capacitive.

In one embodiment, the impedance of the impedance device 540 is related to the expected electrical impedance (Z) of the sound transducer by 1/n. The value n is chosen preferably so that the voltage drop across the impedance device is not too great, for example n=9. In the exemplary embodiment, the feedback resistor 504 has a value related to the input resistor 502 by the same factor n. In the exemplary embodiment, increasing the factor n increases the sensitivity of the mismatch detection circuit, but at the cost of attenuating the audio signal applied to the speaker. Thus there is a trade-off that must be managed according to the requirements of the particular application. Selecting n =10 will attenuate the audio signal by a factor of approximately 10 percent, which is acceptable for audio application. For some proximity detector applications, it may be desirable increase the sensitivity of the mismatch detection circuit.

The relationship between the changes in speaker impedance and the output of the mismatch detection circuit is as follows. Assuming high input impedance at the inverting input of the operational amplifier, a voltage divider formed by R and nR produces the following voltage at the inverting input 522 of the operational amplifier:

$${v}_{-} = {v}_{1} + \frac{R}{R + n R} ( {v}_{o} - {v}_{1} ) = {v}_{1} + \frac{1}{n + 1} ( {v}_{0} - {v}_{1} ) ⇒ {v}_{0} = ( n + 1 ) {v}_{-} - {nv}_{1} \qquad ( 1 )$$

Due to negative feedback and assuming a high open loop gain for the operational amplifier, it follows that:

ν=ν₊=ν₂

∴νₒ=(n+1)ν₂−nν₁ (2)

If the actual speaker impedance is Z, a voltage divider formed by Z/n and Z produces the following voltage at the non-inverting input 526 of the operational amplifier:

$${v}_{2} = \frac{Z}{Z + \frac{Z}{n}} = {v}_{1} = \frac{n}{n + 1} {v}_{1} \qquad ( 3 )$$

The output voltage of the operational amplifier when the impedance is matched is:

$${v}_{o} = ( n + 1 ) {v}_{2} - n {v}_{1} = ( n + 1 ) \frac{n}{n + 1} {v}_{1} - {nv}_{1} = 0 \qquad ( 4 )$$

In the case of an impedance mismatch where the actual speaker impedance is kZ, instead of Z (k=1 for a matching impedance):

$$\begin{matrix}{v}_{o} = ( n + 1 ) {v}_{2} - n {v}_{1} = ( n + 1 ) \frac{k}{k + \frac{1}{n}} {v}_{1} - {nv}_{1} = \frac{k - 1}{k + \frac{1}{n}} {v}_{1} & ( 5 ) \\ If k >> \frac{1}{n} , then {v}_{o} ≅ ( 1 - \frac{1}{k} ) {v}_{1} & ( 6 )\end{matrix}$$

The mismatch detection circuit 500 determines change in the electrical impedance of the sound transducer by producing a voltage at the output of the operational amplifier 520 corresponding to mismatch between an actual electrical impedance of the sound transducer and a reference electrical impedance of the sound transducer. The output of the operational amplifier changes with changes in the electrical impedance of the sound transducer, which in turn changes with changes in the acoustic impedance thereof. In other embodiments, other circuits may be used to detect changes in the electrical impedance of the sound transducer.

In one embodiment, measurement of the actual electrical impedance of the sound transducer during the operation may be made by inputting a test tone to the signal input, at one or more particular frequencies, for example where the impedance change is most significant, as discussed more fully below. In wireless communications handset and other audio applications, some test tones may bothersome to the user, and thus it may be desirable to select a test tone having low amplitude and/or a short time duration to avoid annoying the user. In other embodiments, the actual audio signal intended to be heard by the user is used for determining impedance mismatch.

In one embodiment, in FIG. 4, the output of the mismatch detection circuit is coupled to a compensation estimator 440 that determines audio signal compensation based upon the output of the mismatch detection circuit 430. In one embodiment, the compensation estimator 440 determines the audio signal compensation based upon empirical audio signal compensation data correlated with changes in the detected electrical parameter that changes with the changing acoustic impedance of the speaker for a particular desired frequency response characteristic. This information may be stored in memory on the device, for example in a look-up table. The compensation estimator thus selects the appropriate audio compensation for the mismatch detected.

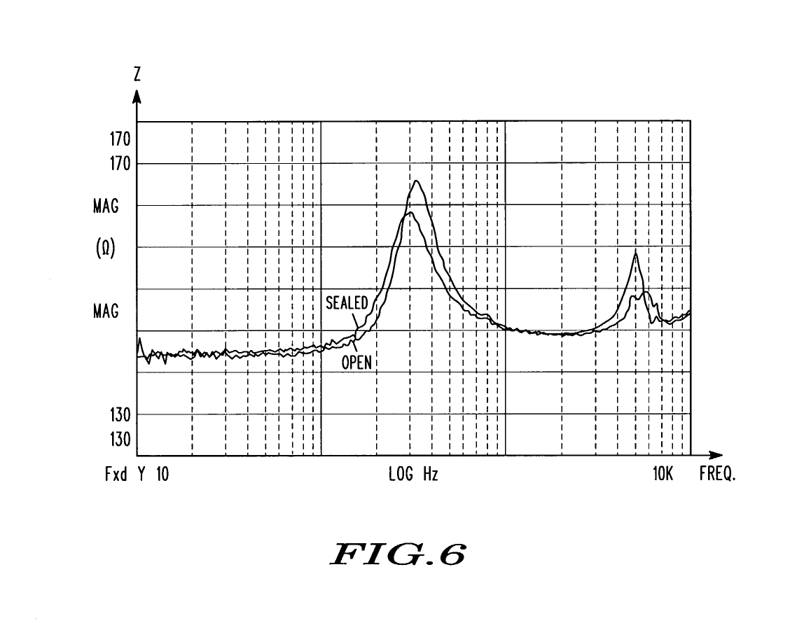

FIG. 6 is a graphical illustration of speaker impedance magnitude versus frequency for a speaker with a sealed coupling and with an open coupling. The graph illustrates that for this particular speaker the electrical impedance varies more at some frequencies than others under sealed and non-sealed acoustic environment conditions. This type of empirical information may form the basis for producing audio signal compensation information required to provide a desired frequency response based upon the variable electrical parameter from the impedance mismatch detection circuit. FIG. 6 also illustrates that, in some embodiments, the electrical impedance only changes significantly at certain frequencies or narrow frequency ranges. These are the frequencies where the electrical impedance change will give a good indication of the acoustic environment change.

In FIG. 4, the compensation estimator 440 has an output coupled to an audio compensator 450. The audio compensator has an audio compensation output coupled to the input of the audio amplifier 420 and then to the sound transducer 410 and the impedance mismatch detection circuit 430. In one embodiment, the audio compensator is a programmable digital filter having an adjustable frequency response and gain. In one embodiment, the function of the compensation estimator and the audio compensator is implemented in software by a digital signal processor (DSP), although in other embodiments it may be implemented in equivalent hardware and/or a combination of hardware and software.

The exemplary circuit of FIG. 4 may also benefit from the addition components to make it more frequency selective at the frequencies of interest, for example by filtering the audio signal with an anti-aliasing filter before converting the audio signal at an A/D converter.

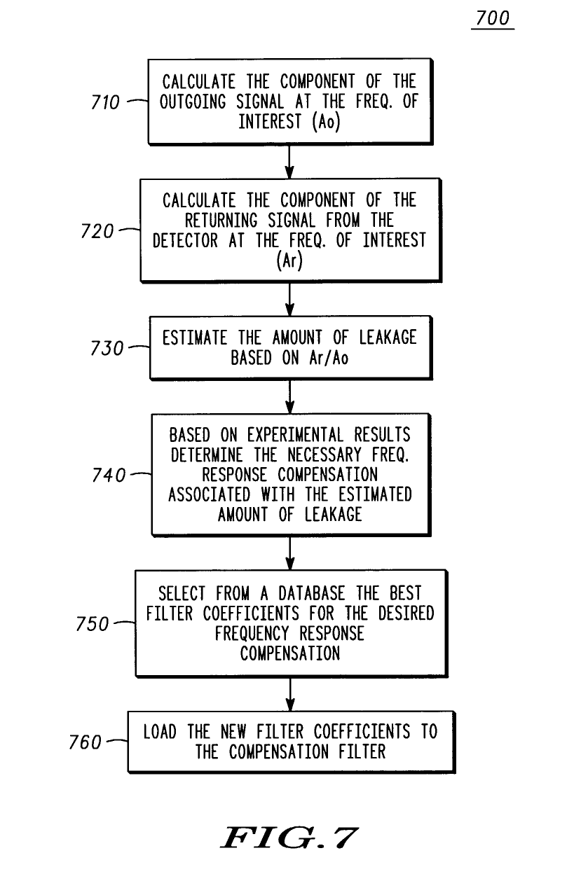

FIG. 7 is an exemplary process flow diagram 700 for compensating an audio signal in an ear-mounted device having a sound transducer susceptible to variable acoustic impedance resulting from varying loads applied thereto, example of which were discussed above. At block 710, the component of the audio signal sent to the speaker is computed, for example by the DSP, at one or more frequencies of interest, preferably at least those frequencies at which the variation in the electrical impedance is most significant. In FIG. 4, the audio signal A_{O} is the signal sent to the audio amplifier 420.

In FIG. 7, the component of the signal AR returning from mismatch detector is computed at the one or more frequencies of interest. In FIG. 4, the return signal A_{R} is the signal output by the mismatch detection circuit 430.

In FIG. 7, at block 730, the change in impedance, or the amount of leakage, is estimated based upon a ratio of A_{R}/A_{O}, which may be computed by the DSP, for example at the compensation estimator 440 in FIG. 4. In FIG. 7, at block 740, audio signal compensation is determined based upon the change in impedance, or the estimated leakage. In FIG. 4, the audio compensation is determined by or at the compensation estimator 440. The audio compensation is determined based upon previously generated experimental results correlating measured changes in impedance with frequency response characteristics for several acoustic coupling environments.

In FIG. 7, at block 750, filter coefficients are selected from a database or lookup table for a desired frequency response, and at block 760 the new filter coefficients are loaded in the programmable filter. The selection of filter coefficients and programming of the filter may be performed by a DSP, for example at the compensation estimator block 440 and the filter block 450 in FIG. 4. The audio signal sent to the speaker is thus compensated dynamically based upon changes in the electrical impedance of the speaker corresponding to changes in the acoustic impedance thereof.

In wireless communications handsets and other ear-mounted audio applications, the adaptive audio compensation methods of the present invention are used preferably in combination with effective acoustic designs.

While the present inventions and what is considered presently to be the best modes thereof have been described in a manner that establishes possession thereof by the inventors and that enables those of ordinary skill in the art to make and use the inventions, it will be understood and appreciated that there are many equivalents to the exemplary embodiments disclosed herein and that myriad modifications and variations may be made thereto without departing from the scope and spirit of the inventions, which are to be limited not by the exemplary embodiments but by the appended claims.

What is claimed is:

1. A method in an electronics device having an ear-mounted sound transducer, comprising:
determining a change in an electrical parameter that changes with changes in an acoustic impedance of the sound transducer;
determining audio signal compensation based upon the change in the electrical parameter;
dynamically compensating an audio signal sent to the sound transducer based upon the audio signal compensation.

2. The method of claim 1, determining the change in the electrical parameter for at least one frequency based upon an audio voice signal sent to the sound transducer.

3. The method of claim 1, determining the change in the electrical parameter by generating a voltage corresponding to a mismatch between an actual electrical impedance of the sound transducer and a reference electrical impedance of the sound transducer.

4. The method of claim 3, determining the change in the electrical parameter at least at a frequency where the mismatch between the actual electrical impedance and the reference electrical impedance is greatest.

5. The method of claim 1, determining the audio signal compensation based upon empirical audio signal compensation data correlated with changes in the electrical parameter for a particular frequency response.

6. The method of claim 1, compensating the audio signal sent to the sound transducer based upon the audio signal compensation by changing at least part of the frequency response or the gain of the audio signal sent to the sound transducer.

7. The method of claim 1, determining the change in the electrical parameter based upon a change in electrical impedance of the sound transducer relative to a reference impedance of the sound transducer.

8. The method of claim 1, changing the electrical impedance of the sound transducer by changing an acoustical impedance of the sound transducer.

9. A method in an electronics device having an ear-mounted sound transducer, comprising:
changing an electrical impedance of the sound transducer by changing an acoustic impedance of the sound transducer;
measuring an electrical parameter that changes with the changing electrical impedance of the sound transducer;
dynamically compensating for the changing acoustic impedance by changing an electrical characteristic of an audio signal sent to the sound transducer based on the electrical parameter.

10. The method of claim 9, measuring the electrical parameter that changes with the changing electrical impedance of the sound transducer for at least one frequency based upon a voice signal sent to the sound transducer.

11. The method of claim 9, changing the electrical characteristic of the audio signal sent to the sound transducer by changing at least part of the frequency response of the audio signal or the gain of the audio signal.

12. The method of claim 9, measuring the electrical parameter that changes with the changing electrical impedance of the sound transducer by producing an electrical signal indicative of a mismatch between a reference electrical impedance of the sound transducer and an actual electrical impedance of the sound transducer.

13. The method of claim 12, changing the electrical characteristic of an audio signal sent to the sound transducer based upon empirical audio signal compensation data previously correlated with the measured electrical parameter.

14. An audio electronics device, comprising:
an audio compensator having an audio signal input and a compensated audio signal output;
a sound transducer coupled to the compensated audio signal output of the audio compensator;
a mismatch detection circuit having a first input coupled to the compensated audio signal output of the audio compensator, the mismatch detecting circuit having a second input coupled to the sound transducer,
the mismatch detection circuit having an output corresponding to a mismatch between a reference electrical impedance of the sound transducer and an actual electrical impedance of the sound transducer;
a compensation estimator having an input coupled to the output of the mismatch detecting circuit, the compensation estimator having an audio compensation output coupled to a compensation input of the audio compensator.

15. The electronics device of claim 14,
an impedance device interconnecting the sound transducer and the compensated audio signal output of the audio compensator;
the mismatch detecting circuit comprises an operational amplifier having its inverting input coupled to the compensated audio signal output of the audio compensator by an input resistor, a feedback resistor interconnecting an output of the operational amplifier and the inverting input of the operational amplifier, the operational amplifier having its noninverting input coupled to the sound transducer.

16. The electronics device of claim 15, the impedance device having an electrical impedance that is less than the reference electrical impedance of the sound transducer.

17. The electronics device of claim 14 is a wireless communications device comprising a processor coupled to memory, a transceiver coupled to the processor, inputs coupled to the processor, a digital signal processor coupled to the processor, the audio compensator and the estimator circuit are part of the digital signal processor.

18. The electronics device of claim 14, the audio compensator is a digital filter having an adjustable frequency response and gain.

19. The electronics device of claim 14, a housing, the sound transducer is disposed within the housing.

20. An electronics device, comprising:
a sound transducer having a signal input;
an operational amplifier having an output and inverting and noninverting inputs, the inverting input of the operational amplifier coupled to a first resistor, the noninverting input of the operational amplifier coupled to the signal input of the sound transducer;
a feedback resistor interconnecting the output of the operational amplifier and the inverting input of the operational amplifier;
an impedance device connected in series with the first resistor between the signal input of the sound transducer and the inverting input of the operational amplifier.

21. A method in an electronics device having a sound transducer, comprising:
changing an electrical impedance of the sound transducer by changing an acoustic impedance of the sound transducer;
measuring an electrical parameter that changes with the changing electrical impedance of the sound transducer;
providing a control signal based on the electrical parameter.

22. The method of claim 21, changing the acoustic impedance of the sound transducer in response to an object moving relative to the sound transducer.
